(19) United States
(12) Patent Application Publication
(10) Pub. No.: US 2025/0308894 A1
(43) Pub. Date: Oct. 2, 2025

(54) HARDMASK FOR HIGH ASPECT RATIO DIELECTRIC ETCH AT CRYO AND ELEVATED TEMPERATURES

(71) Applicant: Lam Research Corporation, Fremont, CA (US)

(72) Inventors: Thorsten Bernd LILL, Kalaheo, HI (US); Ragesh PUTHENKOVILAKAM, Portland, OR (US); Kapu Sirish REDDY, Portland, OR (US); John HOANG, Fremont, CA (US); Meihua SHEN, Fremont, CA (US); Hui-Jung WU, Pleasanton, CA (US); Sonal BHADAURIYA, Beaverton, OR (US); Hao CHI, Union City, CA (US); Aaron Lynn ROUTZAHN, Fremont, CA (US); Anthony Sky YU, Union City, CA (US); Francis Sloan ROBERTS, Portland, OR (US)

(21) Appl. No.: 18/863,211

(22) PCT Filed: May 16, 2023
(86) PCT No.: PCT/US2023/022327

§ 371 Date: Nov. 5, 2024

Related U.S. Application Data
(60) Provisional application No. 63/364,965, filed on May 19, 2022.

(51) Int. Cl. H01L 21/033; H01J 37/32; H01L 21/311; H01L 21/768

(52) U.S. Cl. CPC H01L 21/0332; H01L 21/0337; H01L 21/31116; H01L 21/31144; H01L 21/76814; H01L 21/76843; H01J 37/32449; H01J 2237/3341

(57) ABSTRACT

Various embodiments herein relate to methods, apparatus, and systems for etching high aspect ratio features in dielectric material. The dielectric material is etched using a multi-layer or graded hardmask having at least two different compositions. Different etching regimes are used when the different portions of the hardmask are exposed. For example, a feature may be etched to a first depth at a first temperature while an upper portion of the hardmask is exposed, and then etched to a final depth at a second temperature while a lower portion of the hardmask is exposed, the second temperature being higher than the first temperature.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

One process frequently employed during fabrication of semiconductor devices is etching of dielectric material to form recessed features therein. Example contexts where such a process may occur include, but are not limited to, memory applications such as DRAM and 3D NAND structures. As the semiconductor industry advances and device dimensions become smaller, such features become increasingly difficult to etch.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Various embodiments herein relate to methods, apparatus, and systems for etching features into substrates. The substrates are typically semiconductor substrates, and the features are etched into dielectric material.

In one aspect of the disclosed embodiments, a method of etching a feature into a substrate is provided, the method including: receiving a substrate in a process chamber, the substrate including: dielectric material, and a hardmask including an upper portion and a lower portion, the upper portion including carbon, and the lower portion including at least one material selected from the group consisting of: doped carbon, silicon, a metal, a metal-containing material, and combinations thereof, where the upper portion and lower portion of the hardmask have different compositions, where the hardmask is patterned to define a location where the feature will be etched in the dielectric material, and where the hardmask is positioned over the dielectric material; etching the feature to a first depth into the substrate while the substrate is at a first temperature and while the upper portion of the hardmask is exposed; and etching the feature to a final depth while the substrate is at a second temperature and while the lower portion of the hardmask is exposed, where the second temperature is higher than the first temperature.

Specific temperatures may be used in various embodiments. In some cases, the first temperature is between about −100° C. and about 0° C., and the second temperature is between about 0° C. and about 100° C. In some such cases, the first temperature is between about −60° C. and about −20° C., and the second temperature is between about 20° C. and about 60° C.

The hardmask may include materials having particular compositions. For example, in some embodiments the lower portion of the hardmask includes one or more metal selected from the group consisting of aluminum, boron, chromium, cobalt, hafnium, molybdenum, niobium, ruthenium, tantalum, titanium, tungsten, vanadium, zirconium, and combinations thereof. In various embodiments, the lower portion of the hardmask has a composition that is at least about 5 at % metal.

The method may include one or more additional steps. For example, the method may further include exposing the substrate to an oxygen-containing plasma to ash away any remaining upper portion of the hardmask after etching the feature to the first depth into the substrate and before etching the feature to the final depth. In these or other embodiments, the method may further include depositing a liner on sidewalls of the feature after etching the feature to the first depth into the substrate and before etching the feature to the final depth. In these or other embodiments, the method may further include depositing additional mask material on the hardmask after etching the feature to the first depth into the substrate and before etching the feature to the final depth.

The hardmask may include multiple distinct layers, or it may be graded. In some embodiments, the upper portion and lower portion of the hardmask are distinct layers. In other embodiments, the hardmask has a graded composition, such that a composition of the upper portion of the hardmask is graded into a composition of the lower portion of the hardmask.

In another aspect of the disclosed embodiments, an apparatus for etching a substrate is provided, the apparatus including: a process chamber; a substrate support configured to support the substrate in the process chamber; an inlet to the process chamber for introducing one or more reactants to the process chamber; an outlet to the process chamber for removing materials from the process chamber; a controller including a memory and a processor, where the controller is configured to cause: receiving the substrate in the process chamber, the substrate including: dielectric material, and a hardmask including an upper portion and a lower portion, the upper portion including carbon, and the lower portion including at least one material selected from the group consisting of: doped carbon, silicon, a metal, a metal-containing material, and combinations thereof, where the upper portion and lower portion of the hardmask have different compositions, where the hardmask is patterned to define a location where the feature will be etched in the dielectric material, and where the hardmask is positioned over the dielectric material; etching the feature to a first depth into the substrate while the substrate is at a first temperature and while the upper portion of the hardmask is exposed; and etching the feature to a final depth while the substrate is at a second temperature and while the lower portion of the hardmask is exposed, where the second temperature is higher than the first temperature.

The controller may be configured to cause etching at particular process conditions. For example, in some embodiments the first temperature is between about −100° C. and about 0° C., and the second temperature is between about 0° C. and about 100° C. In some such embodiments, the first temperature is between about −60° C. and about −20° C., and the second temperature is between about 20° C. and about 60° C.

The hardmask may include materials having particular compositions. In some embodiments, the lower portion of the hardmask includes one or more metal selected from the group consisting of aluminum, boron, chromium, cobalt, hafnium, molybdenum, niobium, ruthenium, tantalum, titanium, tungsten, vanadium, zirconium, and combinations thereof. In some such embodiments, the lower portion of the hardmask has a composition that is at least about 5 at % metal.

The controller may be further configured to cause additional operations. For instance, in some embodiments the controller is further configured to cause exposing the substrate to an oxygen-containing plasma to ash away any remaining upper portion of the hardmask after etching the feature to the first depth into the substrate and before etching the feature to the final depth. In these or other embodiments controller may be further configured to cause depositing a liner on sidewalls of the feature after etching the feature to the first depth into the substrate and before etching the feature to the final depth. In these or other embodiments, the controller may be further configured to cause depositing additional mask material on the hardmask after etching the feature to the first depth into the substrate and before etching the feature to the final depth.

The hardmask may include multiple distinct layers, or it may be graded. In some embodiments, the upper portion and lower portion of the hardmask are distinct layers. In other embodiments, the hardmask has a graded composition, such that a composition of the upper portion of the hardmask is graded into a composition of the lower portion of the hardmask.

These and other aspects are described further below with reference to the drawings.

### BRIEF DESCRIPTION OF THE DRAWINGS

FIGS. 1A and 1B show high aspect ratio features and different etching mechanisms that may be used, with FIG. 1A showing an etch process at cryogenic temperatures and FIG. 1B showing an etch process at conventional temperatures

FIGS. 2A and 2B illustrate mechanisms that may be used to etch various types of mask materials when etching at either cryogenic temperatures (FIG. 2A) or at conventional temperatures (FIG. 2B)

FIGS. 3A-3D depict etching mechanisms that can occur during reactive ion etching using different etching temperature regimes and different types of mask layers.

FIG. 4 shows a flowchart for a method of etching features in dielectric materials.

FIGS. 5A-5C show a schematic illustration of profile evolution according to the process described in FIG. 4.

FIG. 6 shows a flowchart for a method of etching features in dielectric materials with intermittent top mask removal.

FIGS. 7A-7D show a schematic illustration of profile evolution according to the process described in FIG. 6.

FIG. 8 shows a flowchart for a method of etching features in dielectric materials with intermittent top mask removal and liner deposition.

FIGS. 9A-9E show a schematic illustration of profile evolution according to the process described in FIG. 8.

FIG. 10 shows a flowchart for a method of etching features in dielectric materials with intermittent top mask removal, liner deposition, and mask regrowth.

FIGS. 11A-11E show a schematic illustration of profile evolution according to the process described in FIG. 10.

FIGS. 12A-12C illustrate an embodiment of an adjustable gap capacitively coupled confined RF plasma reactor according to various embodiments herein.

FIG. 13 shows a semiconductor process cluster architecture with various modules that interface with a vacuum transfer module.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

### Context and Applications

In various embodiments herein, features are etched in a substrate (typically a semiconductor wafer) having dielectric material on the surface. The etching processes are generally plasma-based etching processes such as reactive ion etching processes. A feature is a recess in the surface of a substrate. Features can have many different shapes including, but not limited to, cylinders, ovals, rectangles, squares, other polygonal recesses, trenches, etc.

Aspect ratios are a comparison of the depth of a feature to the critical dimension of the feature (often its width/diameter). For example, a cylinder having a depth of 2 μm and a width of 50 nm has an aspect ratio of 40:1, often stated more simply as 40. As used herein, aspect ratios are measured based on the critical dimension proximate the opening of the feature, unless otherwise stated.

The features formed through the disclosed methods may be high aspect ratio features. In some applications, a high aspect ratio feature is one having an aspect ratio of at least about 5, at least about 10, at least about 20, at least about 30, at least about 40, at least about 50, at least about 60, at least about 80, or at least about 100. The critical dimension of the features formed through the disclosed methods may be about 200 nm or less, for example about 100 nm or less, about 50 nm or less, or about 20 nm or less.

The material into which the feature is etched may be a dielectric material in various cases. Example materials include, but are not limited to, silicon oxides, silicon nitrides, silicon carbides, oxynitrides, oxycarbides, carbo-nitrides, doped versions of these materials (e.g., doped with boron, phosphorus, etc.), and laminates from any combinations of these materials. Particular example materials include stoichiometric and non-stoichiometric formulations of SiO₂, SiN, SiON, SiOC, SiCN, etc. In various embodiments, the material into which the feature is etched includes a stack of alternating materials, such as silicon oxide and silicon nitride. The material or materials being etched may also include other elements, for example hydrogen in various cases. In some embodiments, a nitride and/or oxide material being etched has a composition that includes hydrogen. As used herein, it is understood that silicon oxide materials, silicon nitride materials, etc. include both stoichiometric and non-stoichiometric versions of such materials, and that such materials may have other elements included, as described above.

One application for the disclosed methods is in the context of forming a DRAM device. In this case, the feature may be etched primarily in silicon oxide. The substrate may also include one, two, or more layers of silicon nitride, for instance. In one example, a substrate includes a silicon oxide layer sandwiched between two silicon nitride layers, with the silicon oxide layer being between about 800-1200 nm thick and one or more of the silicon nitride layers being between about 300-400 nm thick. The etched feature may be a cylinder having a final depth between about 1-3 μm, for example between about 1.5-2 μm. The cylinder may have a width between about 20-50 nm, for example between about 25-30 nm. After the cylinder is etched, a capacitor memory cell can be formed therein.

Another application for the disclosed methods is in the context of forming a vertical NAND (VNAND, also referred to as 3D NAND) device. In this case, the material into which the feature is etched may have a repeating layered structure. For instance, the material may include alternating layers of oxide (e.g., SiO₂) and nitride (e.g., SiN), or alternating layers of oxide (e.g., SiO₂) and polysilicon. The alternating layers form pairs of materials. In some cases, the number of pairs may be at least about 20, at least about 30, at least about 40, at least about 60, or at least about 70. The oxide layers may have a thickness between about 20-50 nm, for example between about 30-40 nm. The nitride or polysilicon layers may have a thickness between about 20-50 nm, for example between about 30-40 nm. The feature etched into the alternating layer may have a depth between about 2-8 μm, for example between about 3-5 μm. The feature may have a width between about 50-150 nm, for example between about 50-100 nm.

### Challenges

There are a number of issues that can arise when etching recessed features. These issues include, e.g., non-vertical etch profiles, bowing, twisting, ellipticity, and selectivity. In many etching applications, a recessed feature is etched more extensively near the top of the feature compared to the bottom of the feature. This non-vertical etch profile (e.g., features having slanted sidewalls) is undesirable at least because such profiles limit how closely the features can be positioned next to one another without compromising the integrity of the semiconductor device.

In various etching applications, a recessed feature is etched more extensively near the middle portion of the feature compared to the top and bottom of the feature. This results in a bow near the middle of the feature, where it is widest. Like the non-vertical etch profile mentioned above, such bowing is undesirable at least because it limits how closely the features can be positioned next to one another without compromising the integrity of the semiconductor device.

Twisting is another problem that can occur during etching. Twisting refers to a feature deviating away from its intended position as the feature is etched further into the dielectric material. Another factor to consider when etching is ellipticity, which relates to the shape of a recessed feature. In many cases, the recessed feature is a cylinder. The cross-sectional shape of such a feature, when viewed from above, is a circle. During etching, this circle may become distorted into an ellipse having a major axis and a minor axis. Ellipticity is a measure that compares the major and minor axes (e.g., ellipticity=(B−A)/B, where A is the minor axis length and B is the major axis length) to provide a measurement of circularity vs. ellipticity of the feature. An ellipticity of 0 means that the feature has a perfectly circular cross section, which is desirable.

Another important issue relevant during etching is selectivity. Selectivity relates to the degree to which an etching process removes a first material with respect to a second material. Typically, the dielectric material being etched is positioned between an underlying layer (e.g., an etch stop layer or other type of layer) and an overlying mask layer. The mask layer is patterned through photolithography and related processes to define where the features are to be formed in the dielectric material. High selectivity between the mask layer and the dielectric material allows the feature to be etched deep into the dielectric material. By contrast, when the selectivity between the mask layer and the dielectric material is not sufficiently high, the mask layer may be etched away before the features reach their desired depth in the dielectric material. Another type of selectivity that should be considered is the selectivity between the dielectric material and the underlying material. It is desirable to have high selectivity between these materials to ensure that the dielectric material can be fully removed without substantially removing the underlying material.

Various etching strategies have been developed to address these challenges. Often, a strategy undertaken to address a first challenge will provide inferior performance with respect to a second challenge. As such, it can be difficult to design a process that adequately balances all of the relevant issues.

### Methods

One strategy that may be used to address the challenges described above is to combine two different etching techniques to form the features in the dielectric material. In various embodiments herein, etching occurs through a two-stage process that involves (1) a first reactive ion etching process performed at cryogenic etch temperatures, and (2) a second reactive ion etching process performed at conventional etch temperatures. The first etching process may be used to etch the majority of the feature depth. The second etching process may be used to etch the remaining portion of the feature. A multi-layer hardmask is provided above the dielectric material being etched. The multi-layer hardmask includes (1) an upper layer designed to be used during the first reactive ion etching process performed at cryogenic temperatures, and (2) a lower layer designed to be used during the second reactive ion etching process performed at conventional temperatures. Example materials for each layer of the multi-layer hardmask are discussed below. Use of the multi-layer hardmask allows for optimization of each portion of the etching process, resulting in superior etch performance.

As used herein, the term “conventional etch” is intended to refer to a reactive ion etching process that occurs at conventional, non-cryogenic temperatures. Cryogenic etch processes may occur at temperatures between about −100° C. and about 0° C. Conventional etch processes may occur at temperatures between about 0° C. and about 100° C. More detailed temperature ranges are discussed below.

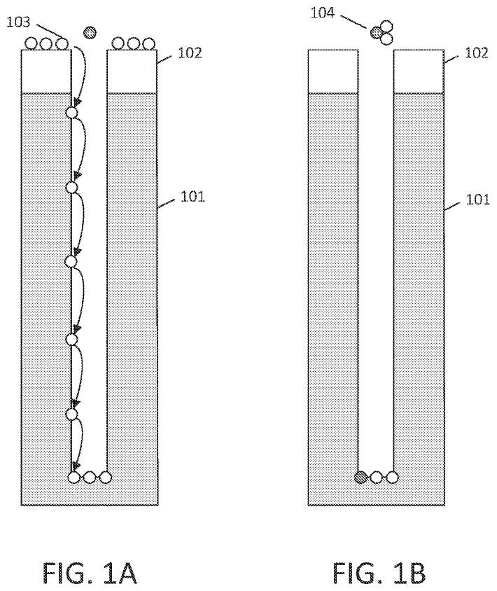

FIGS. 1A and 1B illustrate a high aspect ratio feature and different etching mechanisms that may be used, with FIG. 1A showing an etch process at cryogenic temperatures and FIG. 1B showing an etch process at conventional temperatures. Each of FIGS. 1A and 1B depict a substrate having a feature formed in dielectric material 101. The feature is formed at an opening in the mask 102. As shown in FIG. 1A, in many cases where etching occurs at cryogenic temperatures, the etching relies on fluorine neutral transport to the bottom of the feature, which occurs via surface diffusion of physisorbed molecules containing fluorine 103. Activation occurs through ion bombardment. By contrast, as shown in FIG. 1B, in many cases where etching occurs at conventional temperatures, etching occurs via chemical sputtering by CxFy ions 104.

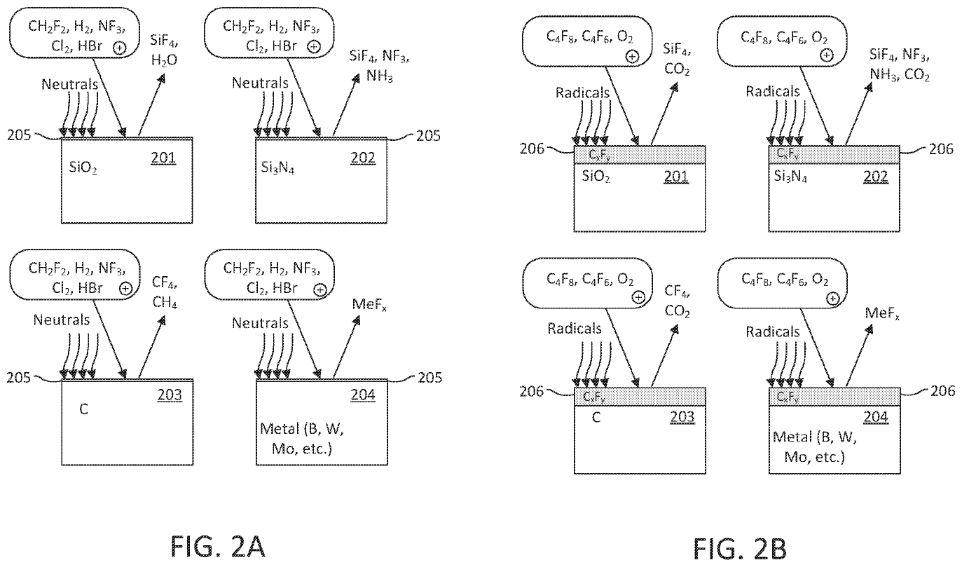

FIGS. 2A and 2B illustrate mechanisms that may be used to etch various types of mask materials when etching at either cryogenic temperatures (FIG. 2A) or at conventional temperatures (FIG. 2B). Each of FIGS. 2A and 2B illustrate four substrates, each substrate having a different material used for the mask layer. A first mask layer 201 is silicon oxide (e.g., SiO₂), a second mask layer 202 is silicon nitride (e.g., Si₃N₄), a third mask layer 203 is carbon (e.g., amorphous carbon), and a fourth mask layer 204 is metal (e.g., boron, tungsten, molybdenum, etc.). As shown in FIG. 2A, when etching occurs at cryogenic temperatures, a thin fluorinated layer 205 develops on the surface of the mask layer 201-204 upon exposure of the substrate to an etching reactant and plasma. The fluorinated layer 205 may be about 1 nm thick. The mask etch rate is driven by chemical intermolecular bonding between fluorides in the etching reactant and the material of the mask layer 201-204. In this example, the etching reactant includes a mixture of CH₂F₂, H₂, NF₃, Cl₂, and HBr. However, other chemistries and combinations of chemistries may be used in various embodiments, as described further below.

As shown in FIG. 2B, when etching occurs at conventional temperatures, a CₓF_{y} salvage layer 206 develops on the surface of the mask layer 201-204 upon exposure of the substrate to an etching reactant and plasma. The CₓF_{y} salvage layer 206 may have a thickness on the order of about 5-10 nm, substantially thicker than the fluorinated layer 205 that forms when etching at cryogenic temperatures. The mask etch rate in this example is driven by carbon consumption (e.g., within the CₓF_{y} salvage layer 206), and diffusion through the CₓF_{y} salvage layer 206. In this example, the etching reactant includes a mixture of C₄F₈, C₄F₆, and O₂. However, other chemistries and combinations of chemistries may be used in various embodiments, as described further below.

The etching mechanisms described in FIGS. 1A-1B and 2A-2B result in different performance benefits and drawbacks for each type of mechanism. For example, the cryogenic etching regime described in relation to FIGS. 1A and 2A provides relatively fast etching with excellent profile control, a high degree of selectivity between the dielectric and the mask material, a low degree of ellipticity, a low degree of twisting, and a low degree of bowing. These factors make cryogenic etching a good candidate for etching the majority of the feature depth. On the other hand, the conventional etching regime described in relation to FIGS. 1B and 2B provides excellent selectivity performance with regard to etching the dielectric material vs. the material of the underlying layer. This factor makes conventional etching a good candidate for etching the features to their final depth after they have been partially etched (e.g., to a first depth) at cryogenic temperatures.

As mentioned above, in embodiments herein a multi-layer hardmask is used. The hardmask includes an upper layer to be used while etching at cryogenic temperatures and a lower layer to be used while etching at conventional temperatures. The upper layer of the hardmask may be substantially consumed while etching at cryogenic temperatures, thereby exposing the lower layer of the hardmask. The use of a multi-layer hardmask allows for each layer of the hardmask to be optimized for the type of etching process that is being used while that particular layer of the hardmask is exposed. This enables fast, high quality etching results while minimizing material and operating costs. For example, material costs can be minimized because the required mask thickness may be thinner than would otherwise be required with a single homogeneous mask layer. Likewise, operating costs can be minimized due to how quickly the features can be etched, thereby requiring less energy and providing greater throughput compared to slower methods.

In order to maximize the benefits of the disclosed embodiments, the materials for the upper and lower layers of the multi-layer hardmask may be selected to optimize each portion of the etching process. Generally, the upper layer of the multi-layer hardmask is carbon (e.g., amorphous carbon), and the lower layer of the multi-layer hardmask is a different material such as doped carbon, silicon, a metal, or a metal-containing material (e.g., a metal oxide, a metal nitride, a metal silicide, metal carbide, metal alloy, etc.). These materials are further discussed below.

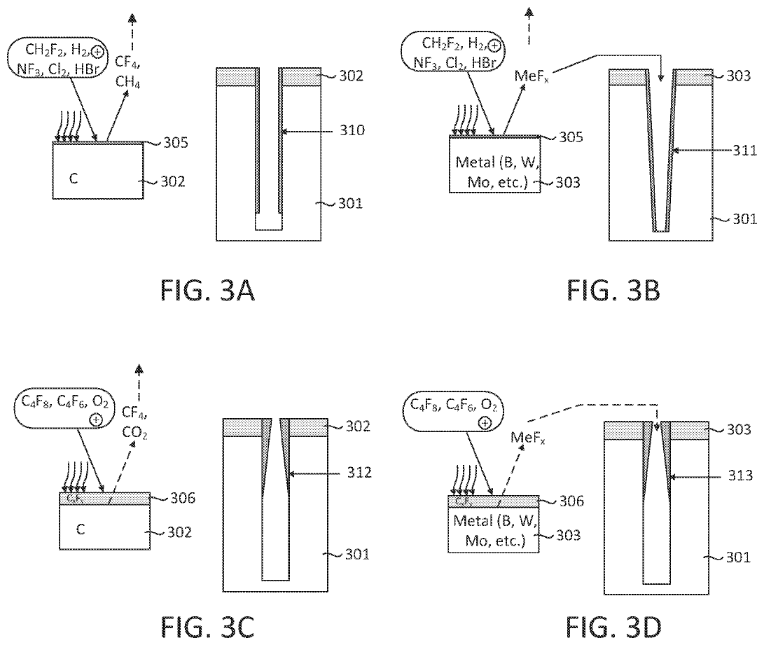

FIGS. 3A-3D depict etching mechanisms that can occur during reactive ion etching using different etching temperature regimes and different types of mask layers. FIG. 3A shows etching at cryogenic temperatures using a carbon mask 302, FIG. 3B shows etching at cryogenic temperatures using a doped carbon mask 303, FIG. 3C shows etching at conventional temperatures using a carbon mask 302, and FIG. 3D shows etching at conventional temperatures using a doped carbon mask 303. Where a doped carbon mask 303 is used, the carbon is doped with metal. While FIGS. 3B and 3D show only the metal in the mask layer (e.g., excluding the carbon in the mask layer), it is understood that this metal may be provided in the form of carbon doped or otherwise mixed with the relevant metal(s).

Each of FIGS. 3A-3D depict a substrate having a feature formed in a layer of dielectric material 301. The location of the feature is defined by an opening in the mask layer (e.g., carbon mask 302 or doped carbon mask 303). As shown in FIG. 3A, where etching occurs at cryogenic temperatures using a carbon mask 302, a sidewall film 310 forms on the sidewalls of the feature. The sidewall film 310 is a silicon-containing ammonium fluoride film that helps protect the sidewalls from becoming over-etched, thereby providing a vertical etch profile with a low degree of bowing, slanting, twisting, and ellipticity. These results are highly desirable. As mentioned above in relation to FIG. 2A, during cryogenic etching a thin fluorinated layer 305 forms on the surface of the carbon mask 302.

As shown in FIG. 3B, where etching occurs at cryogenic temperatures using a doped carbon mask 303, a sidewall film 311 forms on sidewalls of the feature. The sidewall film 311 is a silicon-containing ammonium fluoride film having metal and/or metal fluoride therein. The metal may originate from the doped carbon mask 303. The metal from the doped carbon mask 303 in sidewall film 311 can lead to formation of a non-vertical, tapered etch profile. These results are less than ideal. As mentioned above in relation to FIG. 2A, during cryogenic etching a thin fluorinated layer 305 forms on the surface of the carbon doped mask 303.

As shown in FIG. 3C, where etching occurs at conventional temperatures using a carbon mask 302, a sidewall film 312 forms on the sidewalls of the feature. The sidewall film 312 is a CₓF_{y} film, similar to the CₓF_{y} salvage layer 306 that forms on top of the carbon mask 302. This sidewall film 312 may deposit in a non-conformal manner, with thicker deposition near the top of the feature and little or no deposition near the bottom of the feature. This can lead to formation of bowing and other undesirable etch profile characteristics.

As shown in FIG. 3D, where etching occurs at conventional temperatures using a doped carbon mask 303, a sidewall film 313 forms on the sidewalls of the feature. The sidewall film 313 is a CₓF_{y} film that may include some metal and/or metal fluoride. The metal in the sidewall film may originate from the metal in the doped carbon mask 303. During etching at conventional temperatures, a CₓF_{y} salvage layer 306 may form on the doped carbon mask 303, as described above in relation to FIG. 2B. Like the mechanism shown in FIG. 3C, the mechanism shown in FIG. 3D can form the sidewall film 313 in a non-conformal manner, leading to formation of bowing, twisting, and other undesirable etch profile characteristics. Generally, sidewall film 313 formed during etching at conventional temperatures contains less metal than sidewall film 311 formed during etching at cryogenic temperatures. The formation of tapered profiles is therefore less likely with sidewall film 313 compared to sidewall film 311.

Because the conventional temperature etch mechanisms shown in FIGS. 3C and 3D often lead to undesirable etch profiles, these techniques should not be used for etching the bulk of the feature depth. Instead, the majority of the feature depth is etched using the technique described in relation to FIG. 3A, which involves etching at cryogenic temperatures using a carbon mask. The final portion of the feature depth can be etched using the mechanism shown in FIG. 3D, which provides distinct benefits with regards to selectivity (specifically the selectivity with regard to the underlying layer positioned directly below the dielectric material).

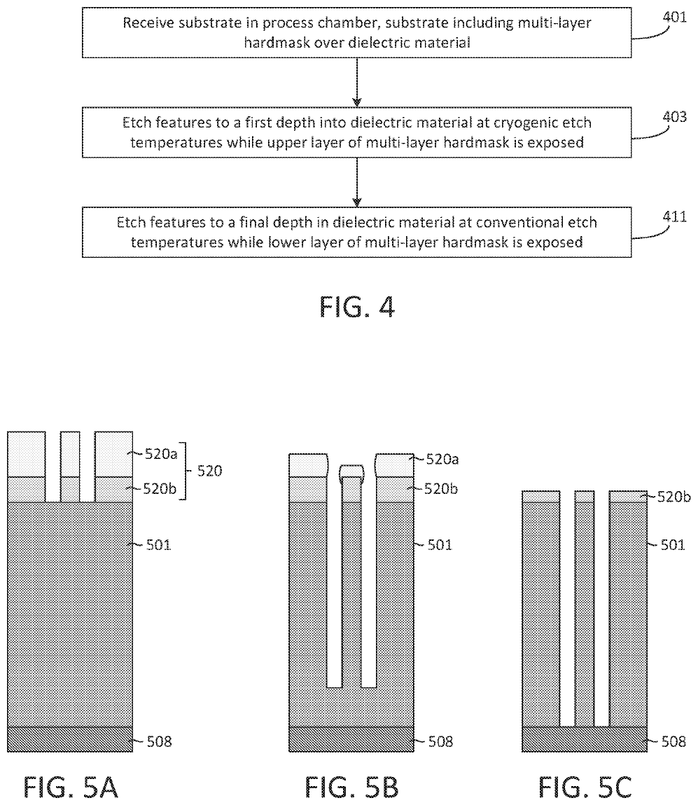

FIG. 4 is a flowchart for a method of etching features in dielectric material according to various embodiments herein. The method of FIG. 4 is described in the context of FIGS. 5A-5C, which show a semiconductor substrate as it undergoes various processing operations of FIG. 4. The method of FIG. 4 begins at operation 401, where a substrate is received in a process chamber. As shown in FIG. 5A, the substrate includes one or more layers of dielectric material 501 into which the features are to be etched. Underlying the dielectric material 501 is an etch stop layer 508. Overlying the dielectric material 501 is a patterned multi-layer hardmask 520, which includes upper layer 520a and lower layer 520b. The upper layer 520a of the multi-layer hardmask 520 is carbon (e.g., amorphous carbon). The upper layer 520a may have a particular thickness in various embodiments. For example, the upper layer 520a may have a minimum thickness of about 1500 nm, or about 1250 nm, or about 1000 nm. In these or other embodiments, the upper layer 520a may have a maximum thickness of about 2500 nm, or about 3000 nm, or about 3500 nm.

The lower layer 520b of the multi-layer hardmask 520 is a material such as doped carbon, silicon, a metal, or a metal-containing material (e.g., a metal oxide, a metal nitride, a metal silicide, metal carbide, metal alloy, etc.). Example metals and other materials for the lower layer 520b are discussed further below. The lower layer 520b may have a particular thickness in various embodiments. For example, the lower layer 520b may have a minimum thickness of about 1000 nm, or about 500 nm, or about 200 nm. In these or other embodiments, the lower layer 520b may have a maximum thickness of about 2000 nm, or about 1500 nm, or about 1250 nm.

The multi-layer hardmask 520 may have a particular total thickness. This total thickness includes the thickness of both the upper layer 520a and the lower layer 520b prior to etching the dielectric material 501. The total thickness may be a minimum of about 2500 nm, or about 2000 nm, or about 1500 nm. In these or other embodiments, the total thickness may be a maximum of about 4000 nm, or about 3500 nm, or about 3000 nm. The multi-layer hardmask 520 is patterned to include openings therein. These openings define the locations where the features will be etched in the dielectric material 501. The openings may be formed through photolithography and related processes. The openings may have dimensions as described herein.

Returning to the embodiment of FIG. 4, the method continues with operation 403, where the features are etched to a first depth into the dielectric material using cryogenic etch temperatures. This cryogenic etch process is used to etch the majority of the feature depth, as shown in FIG. 5B. In various embodiments, cryogenic etch temperatures may be used to etch a particular portion of the features (e.g., at the top of the features). For example, this portion may be at least about 50% of the final etch depth, at least about 75% of the final etch depth, at least about 90% of the final etch depth, at least about 95% of the final etch depth, at least about 98% of the final etch depth, or at least about 99% of the final etch depth.

During etching at cryogenic temperatures, the substrate is cooled to a relatively low temperature. For example, a substrate support may be cooled to maintain a low temperature on the substrate. Example minimum substrate support temperatures may be about −100° C., about −80° C., about −60° C., or about −40° C. Example maximum substrate support temperatures may be about −50° C., about −20° C., or about 0° C.

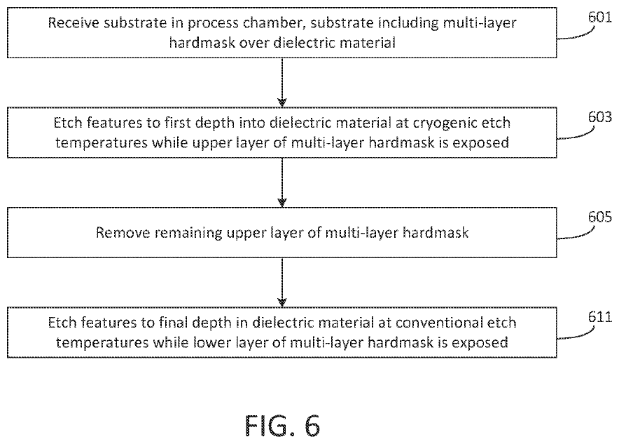

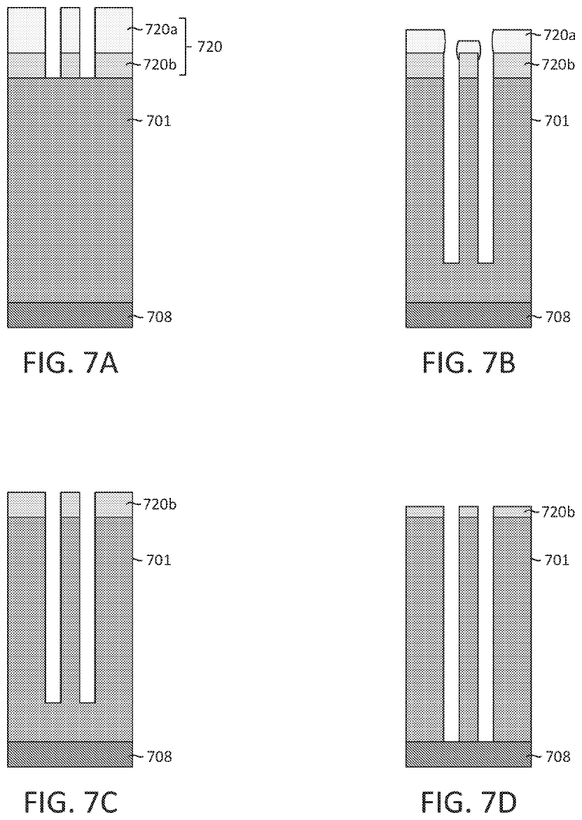

An etching reactant and plasma are provided to the process chamber, and the substrate is exposed to the etching reactant and plasma. During this etching operation (or a substantial portion thereof), the upper layer 520a of the multi-layer hardmask 520 is exposed to the process conditions and the lower layer 520b of the multi-layer hardmask 520 is protected by the upper layer 520a. In some embodiments, the upper layer 520a may be consumed to expose the lower layer 520b at some point near the end of operation 403 or the beginning of operation 411. In some embodiments, the upper layer 520a may be only partially consumed during etching, and a separate optional step may be taken to remove any remaining upper layer 520a, as described in relation to FIGS. 6 and 7A-7D, below. In various embodiments, the dielectric material 501 may be etched according to the mechanism shown in FIG. 3A (which shows cryogenic etching using a carbon mask) during operation 403.

The etching reactant used during operation 403 typically includes a mixture of reactants. One example mixture is shown in FIGS. 2A, 3A, and 3B, and includes CH₂F₂, H₂, NF₃, Cl₂, and HBr. However, other chemistries and combinations of chemistries may be used in various embodiments, as described further below. Such chemistries may include, e.g., fluorocarbons and hydrofluorocarbons (e.g. trifluoromethane (CHF₃), tetrafluoromethane (CF₄), hexafluoroethane (C₂F₆), octafluoropropane (C₃F₈), etc.), iodine-containing fluorocarbons (e.g., trifluoromethyl iodide (CF₃I), iodopentafluoroethane (C₂IF₅), diiodotetrafluoroethane (C₂I₂F₄), pentafluoroethyl iodide (C₂F₅I), etc.), iodine-containing fluorides (e.g., iodine monofluoride (IF), iodine trifluoride (IF₃), iodine pentafluoride (IF₅), iodine heptafluoride (IF₇), etc.), hydrogen iodide (HI), bromine-containing fluorocarbons (e.g., tribromotrifluoroethane (C₂Br₃F₃), dibromotetrafluoroethan (C₂Br₂F₄), bromopentafluoroethane (C₂BrF₅), bromotrifluoromethane (CF₃Br), etc.), other bromine-containing reactants (e.g., iodine monobromide (IBr), hydrogen bromide (HBr), etc.), sulfur-containing reactants (e.g. sulfur hexafluoride (SF₆), hydrogen sulfide (H₂S), sulfur dioxide (SO₂), carbon disulfide (CS₂) carbonyl sulfide (COS), and other sulfur-containing reactants). In these or other embodiments, the chemistry may include one or more etchants such as nitrogen trifluoride (NF₃), difluoromethane (CH₂F₂), fluoromethane (CH₃F), octafluorocyclobutane (C₄F₈), 1,3 hexafluorobutadiene (C₄F₆), pentafluoroethane (C₂HF₅), tetrafluoroethane (C₂H₂F₄, both isomers: 1,1,1,2-tetrafluoroethane, and 1,1,2,2-tetrafluoroethane). Further, in these or other embodiments, the chemistry may include one or more co-reactants such as methane (CH₄), nitrogen (N₂), oxygen (O₂) and/or hydrogen (H₂). Rare gases (helium, neon, argon, krypton, xenon) may also be added as diluents and/or carrier gases. These chemistries may be combined as desired for a particular application.

Particular process conditions may be used while cryogenic etching in operation 403. For example, a pressure in the processing chamber may be a minimum of about 10 mTorr, or about 20 mTorr. In these or other embodiments, the pressure in the processing chamber may be a maximum of about 100 mTorr, or about 50 mTorr. The flow rate of the etching reactant (excluding any noble or otherwise non-reactive gases) may be a minimum of about 200 sccm, or about 300 sccm. This flow rate may be a maximum of about 500 sccm, or about 1000 sccm. The flow rate of non-reactive gas (e.g., Ar, He, Kr, etc.) may be a minimum of about 200 sccm, or about 100 sccm. In these or other embodiments, the flow rate of non-reactive gas may be a maximum of about 500 sccm, or about 300 sccm. The plasma may be generated at one or more frequencies. Example frequencies include 60 MHz, 27 MHz, 13.65 MHz, 2 MHz, 1 MHz and 400 kHz. The plasma may be generated at a particular power level. For example, this source power level may be a minimum of about 10 kW, or about 15 kW. In these or other cases, this power level may be a maximum of about 20 kW, or about 30 kW. These power levels relate to a single 300 mm diameter semiconductor substrate, and may be scaled appropriately for additional substrates or substrates of other sizes. The substrate may be biased during etching, with the bias power (e.g., at about 400 kHz) ranging between a minimum of about 30 W, or about 50 W, and a maximum of about 75 W, or about 100 W. Various types of plasma may be used including, e.g., inductively coupled plasma, capacitively coupled plasma, transformer coupled plasma, and microwave induced plasma. The plasma may be a direct plasma generated in the process chamber.

Next, at operation 411, the features are further etched into the dielectric material by etching at conventional temperatures. Operation 411 may be used to etch the features to their final depth, as shown in FIG. 5C. In some cases, operation 411 may occur in a single stage. In some other cases, operation 411 may occur in multiple stages, for example a first portion to etch the features and a second portion to overetch the features.

In various embodiments, the upper layer 520a is carbon and the lower layer 520b is carbon doped with one or more metals. The metal doped into the lower layer 520b slows the rate at which the lower layer 520b is consumed. Because the rate at which the dielectric is etched is essentially unchanged (e.g., compared to a case where a single carbon hardmask is used), the decreased mask etch rate results in a higher etch selectivity. This bump in selectivity is particularly advantageous toward the end of the etching process. Various other possible materials listed for the lower layer 520b are expected to provide similar benefits as the doped carbon.

During etching at conventional temperatures, the substrate may or may not be temperature-controlled, for example through heating and/or cooling. For example, a substrate support may be heated and/or cooled to maintain a desired temperature on the substrate. Example minimum substrate support temperatures may be about 20° C., or about 40° C., or about 60° C. Example maximum substrate support temperatures may be about 60° C., or about 80° C., or about 100° C. Higher temperatures may be used in some cases.

During operation 411, an etching reactant and plasma are provided to the process chamber, and the substrate is exposed to the etching reactant and plasma. During this etching operation (or a substantial portion thereof), the lower layer 520a of the multi-layer hardmask 520 is exposed to the process condition. As mentioned above, the upper layer 520a may be consumed to expose the lower layer 520b at some point near the end of operation 403 or the beginning of operation 411, or any remaining upper layer 520a can be removed in a separate step. In various embodiments, the dielectric material 501 may be etched according to the mechanism shown in FIG. 3D (which shows conventional temperature etching using a doped carbon mask) during operation 411.

The etching reactant used during operation 411 typically includes a mixture of reactants. One example mixture is shown in FIGS. 2B, 3C, and 3D, and includes C₄F₈, C₄F₆, and O₂. However, other chemistries and combinations of chemistries may be used in various embodiments. Generally, any of the chemistries described in relation to the cryogenic etch at operation 403 may be used for the conventional temperature etch at operation 411. Such chemistries can be combined as desired for a particular application.

Particular process conditions may be used while performing the conventional temperature etch in operation 411. For example, a pressure in the processing chamber may be a minimum of about 10 mTorr, or about 20 mTorr. In these or other embodiments, the pressure in the processing chamber may be a maximum of about 50 mTorr, or about 100 mTorr. The flow rate of the etching reactant (excluding any noble or otherwise non-reactive gases) may be a minimum of about 200 sccm, or about 300 sccm. This flow rate may be a maximum of about 500 sccm, or about 1000 sccm. The flow rate of non-reactive gas (e.g., Ar, He, Kr, etc.) may be a minimum of about 200 sccm, or about 100 sccm. In these or other embodiments, the flow rate of non-reactive gas may be a maximum of about 500 sccm, or about 300 sccm. The plasma may be generated at one or more frequencies. Example frequencies include 60 MHz, 27 MHz, 13.65 MHz, 2 MHz, 1 MHz, and 400 kHz. The plasma may be generated at a particular power level. For example, this source power level may be a minimum of about 10 kW, or about 15 kW. In these or other cases, this power level may be a maximum of about 20 kW, or about 30 kW. These power levels relate to a single 300 mm diameter semiconductor substrate, and may be scaled appropriately for additional substrates or substrates of other sizes. The substrate may be biased during etching, with the bias ranging between a minimum 400 kHz power of about 30 kW, or about 50 kW, and a maximum of about 75 kW, or about 100 kW. Various types of plasma may be used including, e.g., inductively coupled plasma, capacitively coupled plasma, transformer coupled plasma, and microwave induced plasma. A capacitively coupled plasma is preferred in various embodiments.

FIG. 6 is a flowchart for a method of etching features in dielectric material according to various embodiments herein. The method of FIG. 6 is described in the context of FIGS. 7A-7D, which show a semiconductor substrate as it undergoes various processing operations of FIG. 6. The method of FIG. 6 is similar to the method of FIG. 4. For example, operations 601, 603, and 611 of FIG. 6 are analogous to operations 401, 403, and 411, respectively, of FIG. 4. For the sake of brevity, details related to operations 601, 603, and 611 are mostly excluded. However, it is understood that the details provided with respect to operations 401, 403, and 411 may apply to operations 601, 603, and 611, respectively.

FIG. 7A shows the substrate as it is received in the process chamber in operation 601. The substrate includes dielectric material 701 positioned between an etch stop layer 708 and a multi-layer hardmask 720 including an upper layer 720a and a lower layer 720b. FIG. 7B shows the substrate after the features are etched to the first depth into the dielectric material 701 at cryogenic etch temperatures in operation 603. Returning to the embodiment of FIG. 6, the method continues at operation 605, where any remaining portion of the upper layer 720a of the multi-layer hardmask 720 is removed, as shown in FIG. 7C. This removal may be done in a separate step. In many embodiments, the upper layer 720a is removed through ashing, which involves exposing the substrate to an oxygen plasma. The oxygen in the oxygen plasma reacts with the carbon in the upper layer 720a of the multi-layer hardmask 720 to thereby remove the upper layer 720a.

One advantage to removing the remaining portion of the upper layer 720a is that it provides a substantially uniform mask height for future processing, thereby eliminating any non-uniformities that may have arisen while etching at cryogenic temperatures in operation 703. Such non-uniformities in mask height are seen in FIG. 7B. These non-uniformities are typically a result of non-uniformity in feature layout/density, often referred to as iso/dense loading. Providing a uniform mask height for future process steps may enable such future process steps to occur in a more uniform manner. Another advantage to removing the remaining portion of the upper layer 720a is that it removes any necking that may have developed while etching at cryogenic temperatures in operation 703.

The process conditions used to ash away the remaining upper layer 720a may depend on a number of factors including, e.g., the amount of material to be removed. The oxygen plasma may be generated at one or more frequencies, for example 13.65 MHz, 27 MHz, 40 MHz, and 60 MHz. The oxygen plasma may be generated at a particular power level. This power level may be a minimum of about 200 W, or about 500 W. In these or other embodiments, this power level may be a maximum of about 3000 W, or about 6000 W. The substrate may be controlled to a particular temperature, for example by controlling the temperature of a substrate support. Example minimum temperatures for the substrate support may be about 20° C., or about 50° C. Example maximum temperatures for the substrate support may be about 200° C., or about 250° C. The pressure in the process chamber may be controlled. Example minimum chamber pressure may be about 500 mTorr, or about 750 mTorr. Example maximum chamber pressure may be about 2 Torr, or about 4 Torr. A flow rate of oxygen into the process chamber may be controlled. Example minimum oxygen flow rates include about 500 sccm, or about 1000 sccm. Example maximum oxygen flow rates include about 2000 sccm, or about 4000 sccm. A carrier gas may also be provided. CF₄ can also be added to enhance the dissociation of oxygen and to provide fluorine for removal of silicon-containing etch products.

After any remaining portion of the upper layer 720a is removed in operation 605, the method of FIG. 6 continues with operation 611, where the features are further etched into the dielectric material 701 using conventional etching temperatures, as described in relation to operation 411 of FIG. 4. After etching in operation 611, the features are at their final depth (e.g., reaching the etch stop layer 708), as shown in FIG. 7D.

Although FIG. 6 is presented in the context of an embodiment where all of the remaining portion of the upper layer 720a is removed, it should be understood that this removal may also be partial. In such embodiments, operation 605 may involve removing some, but not all, of the remaining portion of the upper layer 720a. A partial removal may be sufficient to gain one or more benefits described above, such as providing a uniform mask height and/or removing necking.

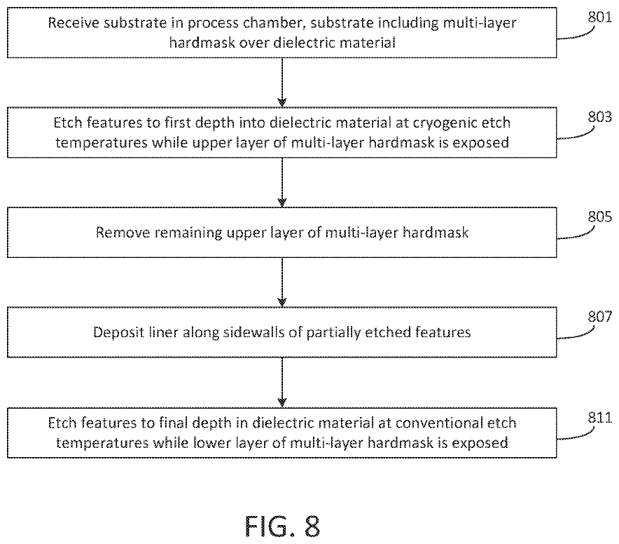

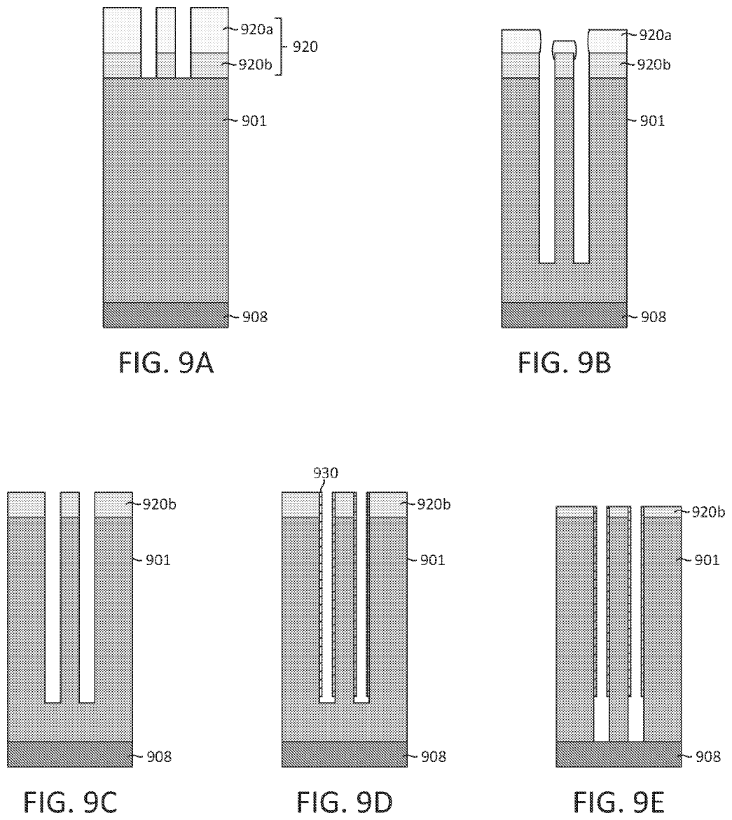

FIG. 8 is a flowchart for a method of etching features in dielectric material according to various embodiments herein. The method of FIG. 8 is described in the context of FIGS. 9A-9E, which show a semiconductor substrate as it undergoes various processing operations of FIG. 8. The method of FIG. 8 is similar to the method of FIGS. 4 and 6. For example, operation 801 of FIG. 8 is analogous to operation 401 of FIG. 4 and to operation 601 of FIG. 6, operation 803 of FIG. 8 is analogous to operation 403 of FIG. 4 and to operation 603 of FIG. 6, operation 805 of FIG. 8 is analogous to operation 605 of FIG. 6, and operation 811 of FIG. 8 is analogous to operation 411 of FIG. 4 and to operation 611 of FIG. 6. For the sake of brevity, details related to operations 801, 803, 805, and 811 are mostly excluded. However, it is understood that details related to operations 401/601, 403/603, 605, and 411/611, may also apply to operations 801, 803, 805, and 811, respectively.

In this example, the features are etched in dielectric material 901, which is positioned between an etch stop layer 908 and a multi-layer hardmask 920 having an upper layer 920a and a lower layer 920b, as shown in FIG. 9A. FIG. 9B shows the substrate after operation 803. FIG. 9C shows the substrate after operation 805. Generally speaking, removal of the upper layer 920a of the multi-layer hardmask in a separate step such as operation 805 is optional, and in some embodiments the method of FIG. 8 may be practiced without operation 805.

The method of FIG. 8 continues with operation 807, where a liner 930 is deposited along the sidewalls of the partially etched features, as shown in FIG. 9D. In many embodiments, this deposition occurs through chemical vapor deposition (CVD), which may or may not involve exposure to plasma. However, other deposition methods such as atomic layer deposition (ALD), self-assembled monolayer (SAM), etc. may also be used. The liner 930 may be a carbon liner in many cases. Other types of liners, such as metal doped carbon, metal nitrides or metal oxides may also be used as desired for a particular application.

The process conditions used to form the liner may be controlled. In various example where CVD is used to deposit a carbon liner, the following conditions may be used. The pressure in the processing chamber may be a minimum of about 1 Torr, or about 5 Torr. This pressure may be a maximum of about 10 Torr, or about 15 Torr. The substrate may be temperature-controlled, for example by heating and/or cooling a substrate support. The substrate support may be controlled to a minimum temperature of about 200° C., or about 300° C. The substrate support may be controlled to a maximum temperature of about 500° C., or about 700° C. A reactant provided to the process chamber may include CₓH_{y} (e.g., CH₄, C₂H₂, C₃H₆, C₄H₈, etc.). A carrier gas may be provided. Example minimum flow rates for the reactant (excluding carrier gas) may be about 20 sccm, or about 100 sccm. Example maximum flow rates for the reactant (excluding carrier gas) may be about 5 slm, or about 10 slm. The plasma can be capacitively or inductively coupled with various frequencies.

As mentioned above, other types of deposition may also be used to form the liner. Where this is the case, the process conditions should be tailored to the type of process being used and the type of material being deposited.

After the liner 930 is deposited on the sidewalls in operation 807, the method of FIG. 8 continues with operation 811, where the features are etched further into the dielectric material 901 using conventional etch temperatures, as shown in FIG. 9E.

In various embodiments, depositing the liner 930 in operation 807 and etching the features at conventional temperatures in operation 911 may be cycled with one another. Such cycling may enable the feature to be etched further into the dielectric material than would otherwise be achievable, all else being equal.

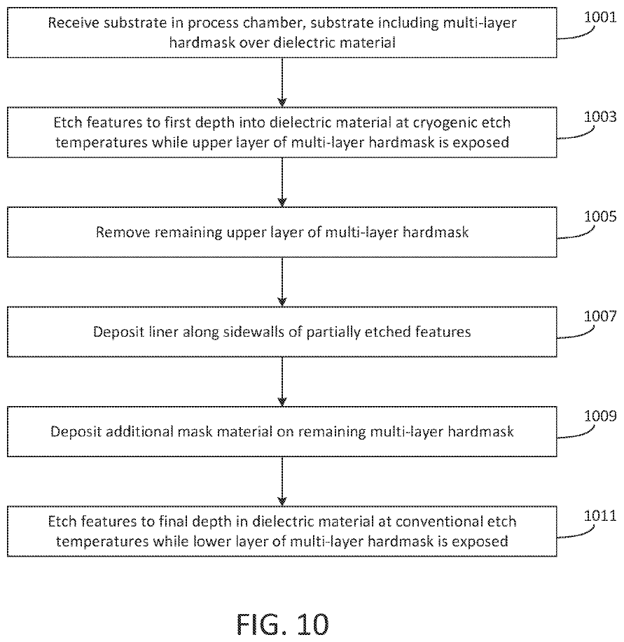

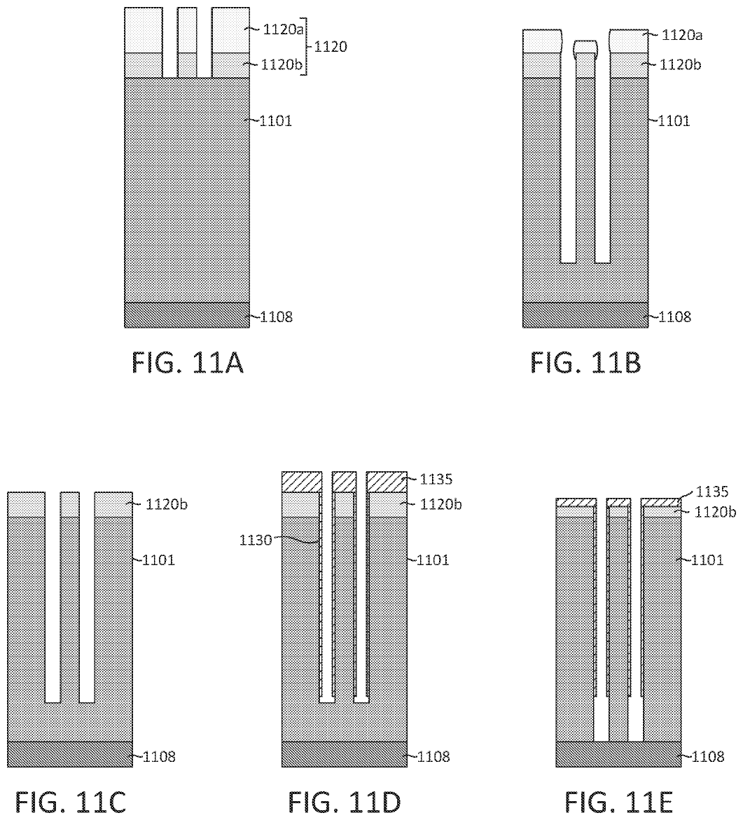

FIG. 10 is a flowchart for a method of etching features in dielectric material according to various embodiments herein. The method of FIG. 10 is described in the context of FIGS. 11A-11E, which show a semiconductor substrate as it undergoes various processing operations of FIG. 10. The method of FIG. 10 is similar to the method of FIGS. 4, 6, and 8. For example, operation 1001 of FIG. 10 is analogous to operations 401, 601, and 801, operation 1003 of FIG. 10 is analogous to operations 403, 603, and 803, operation 1005 of FIG. 10 is analogous to operations 605 and 805, operation 1007 of FIG. 10 is analogous to operation 807, and operation 1011 of FIG. 10 is analogous to operations 411, 611, and 811. For the sake of brevity, details related to operations 1001, 1003, 1005, 1007, and 1011 are mostly excluded. However, it is understood that details related to operations 401/601/801, 403/603/803, 605/805, 807, and 411/611/811, may also apply to operations 1001, 1003, 1005, 1007, and 1011, respectively.

In the method of FIG. 10, features are etched into a substrate having dielectric material 1101 positioned between an underlying etch stop layer 1108 and an overlying multi-layer hardmask 1120 having an upper layer 1120a and a lower layer 1120b, as shown in FIG. 11A. FIG. 11B shows the substrate after etching at cryogenic temperatures in operation 1003. FIG. 11C shows the substrate after removing the remaining upper layer 1120a of the multi-layer hardmask 1120 in operation 1005. The method of FIG. 10 continues with operation 1007, where a liner 1130 is deposited along the sidewalls of the partially etched features, and operation 1009, where additional mask material 1135 is deposited on the remaining portion of the multi-layer hardmask 1120. These operations may occur at the same time, or one may occur before the other. In various embodiments, operations 1007 and/or 1009 occur through chemical vapor deposition, which may or may not involve exposure to plasma.

In various embodiments, the additional mask material 1135 is carbon. The additional mask material 1135 may have the same composition as the carbon forming the upper layer 1120a of the multi-layer hardmask 1120, or it may have the same composition as the doped carbon or other material forming the lower layer 1120b of the multi-layer hardmask 1120, or it may be different from both of these materials.

The process conditions used to form the liner and/or additional mask material may be controlled. In various example where CVD is used, the following conditions may be used. The pressure in the processing chamber may be a minimum of about 1 Torr, or about 5 Torr. This pressure may be a maximum of about 10 Torr, or about 15 Torr. The substrate may be temperature-controlled, for example by heating and/or cooling a substrate support. The substrate support may be controlled to a minimum temperature of about 200° C., or about 300° C. The substrate support may be controlled to a maximum temperature of about 500° C., or about 700° C. A reactant provided to the process chamber may include CₓH_{y} (CH₄, C₂H₂, C₃H₆, C₄H₈, etc.). A carrier gas may be provided. Example minimum flow rates for the reactant (excluding carrier gas) may be about 20 sccm, or about 100 sccm. Example maximum flow rates for the reactant (excluding carrier gas) may be about 5 slm, or about 10 slm. The plasma can be capacitively or inductively coupled with various frequencies.

Other types of deposition may also be used to form the liner and/or additional mask material. Where this is the case, the process conditions should be tailored to the type of process being used and the type of material being deposited.

Any of the methods described herein may be modified such that one or more steps may be repeated. For example, with reference to FIG. 6, removal of a portion of the multi-layer hardmask in operation 605 may be performed repeatedly. In some embodiments, partial mask removal in operation 605 may be cycled with etching at conventional temperatures in operation 611. With reference to FIG. 8, certain additional steps may be done repeatedly. For example, removal of a portion of the multi-layer hardmask in operation 805, deposition of the liner in operation 807, and/or etching of the features at conventional etch temperatures in operation 811 may be repeated. In various embodiments two or more of these operations may be cycled with one another. Similarly, FIG. 10 presents an additional step that may be repeated in some embodiments. For example, removal of a portion of the multi-layer hardmask in operation 1005, deposition of the liner in operation 1007, deposition of additional mask material in operation 1009, and/or etching at conventional etch temperatures in operation 1011 may be repeated. In various embodiments, two or more of these operations may be cycled with one another. Such cycling may enable the features to be etched to a greater depth than would otherwise be achievable.

### Materials for Multi-Layer Hardmask

The multi-layer hardmask includes at least an upper layer and a lower layer. Additional layers may be provided as desired for a particular application. Generally, the upper layer is carbon, and the lower layer is a different material such as doped carbon, silicon, a metal, or a metal-containing material (e.g., a metal oxide, a metal nitride, a metal silicide, metal carbide, metal alloy, etc.).

The carbon in the upper layer of the multi-layer hardmask may be relatively pure, for example at least about 85% carbon, at least about 90% carbon, at least about 95% carbon, at least about 99% carbon, or at least about 99.9% carbon. These measurements are based on at %. In various embodiments, the upper layer includes only carbon and trace amounts of impurities. In some embodiments, the upper layer may be lightly doped carbon, as defined below. Such carbon may be doped with one or more of metals such as those described below. A lightly doped upper layer may be paired with a more extensively doped lower layer, or a lower layer made of a different material. The upper layer may be amorphous or with polycrystalline with grain sizes smaller than 2 nm.

The upper layer of the multi-layer hardmask may be formed through any appropriate deposition method. In some embodiments, it may be formed through CVD.

The lower layer 520b of the multi-layer hardmask 520 is a material such as doped carbon, silicon, a metal, or a metal-containing material (e.g., a metal oxide, a metal nitride, a metal silicide, metal carbide, metal alloy, etc.). Generally, where the lower layer 520b includes a metal, the metal may be present at a minimum concentration of about 0.1%, or about 0.5%, or about 1%, or about 2%, or about 5%, or about 10%, or about 20%, or about 30%, or about 50%. In these or other embodiments, the metal may be present in the lower layer 520b at a maximum concentration of about 5%, about 10%, about 20%, about 50%, or even up to about 100% (e.g., pure metal, or a metal containing only trace impurities, or a metal alloy). These measurements are based on at %.

In some embodiments, the lower layer is carbon that has been lightly doped with one or more metals. For example, carbon that is lightly doped with metal may have up to about 10% metal. In some embodiments, the lower layer is carbon that has been moderately doped with one or more metals. For example, carbon that is moderately doped with metal may have between about 15-35% metal. In some embodiments, the lower layer is carbon that has been heavily doped with one or more metals. For example, carbon that is heavily doped with metal may have between about 40-50% metal. These measurements are based on at %.

In some embodiments, the lower layer is silicon. The silicon may be relatively pure, for example containing only trace amounts of impurities.

In some embodiments, the lower layer is a metal or a metal-containing material. Metal-doped carbon is discussed above. Metal-doped oxides, metal-doped nitrides, metal-doped carbides, and/or metal-doped silicides may also be used. Other metal-containing materials that may be used for the lower layer include, e.g., metal oxides, metal nitrides, metal carbides, and metal silicides. In such embodiments, the metal may be present at stoichiometric levels, sub-stoichiometric levels, or super-stoichiometric levels.

Various different metals may be used. For instance, the lower layer may include one or more metal from the group consisting of aluminum, boron, chromium, cobalt, hafnium, molybdenum, niobium, ruthenium, tantalum, titanium, tungsten, vanadium, zirconium, and combinations thereof. Other metals may be used in some embodiments.

In a number of embodiments, the metal that is included in the lower layer (e.g., in the form of a pure metal, metal-doped carbon, metal oxide, metal nitride, metal carbide, metal silicide, or other metal-doped layer described herein) is one that has a relatively high boiling point when combined with fluorine. For instance, the relevant metal fluoride may have a boiling point that is about equal to or higher than the boiling point of tungsten fluoride at the relevant etch temperature, in some cases equal to or higher than the boiling point of molybdenum fluoride or chromium fluoride or tantalum fluoride. Because the metal in the lower layer reacts with fluorine in the etch chemistry (e.g., via CₓF_{y} chemistry and related chemical sputtering), this leads to formation of metal fluorides. When these metal fluorides are relatively more stable (e.g., higher boiling point, less volatile), it requires more energy to remove them. As such, metals having high boiling point metal fluorides are good candidates for including in the lower layer. Tantalum fluoride (TaF₅), niobium fluoride (NbF₅), titanium fluoride (TiF₄), and hafnium fluoride (HfF₄), among others, are known to have relatively high boiling points.

In some embodiments, the metal that is included in the lower layer is one that has a relatively low reactivity with fluorine. For instance, the relevant metal may be equally or less reactive with fluorine than ruthenium. Because the metal in the lower layer reacts with fluorine in the etch chemistry (e.g., via CₓF_{y} chemistry), selecting a metal that has a low reactivity with fluorine results in a relatively lower mask etch rate when etching the lower layer of the multi-layer hardmask. This results in improved etch selectivity, as described above.

The lower layer of the multi-layer hardmask may be formed through any appropriate deposition method. In some embodiments, it may be formed through CVD. The lower layer may be amorphous or with polycrystalline with grain sizes smaller than 2 nm.

In addition to differences in composition, the upper layer and lower layer may have other material property differences, as well. For example, the lower layer may be more dense than the upper layer.

### Graded Multi-Layer Hardmask

In various embodiments, the multi-layer hardmask described herein may be replaced by a graded layer hardmask, or a multi-layer hardmask having at least one graded layer. With reference to the multi-layer hardmask 520 of FIG. 5A, the graded layer may include a first end or portion that is analogous to the upper layer 520a, a second end or portion that is analogous to the lower layer 520b, and a graded composition between these ends or portions (e.g., with one composition grading into the next along the thickness of the layer). Generally, any details provided herein with respect to a multi-layer hardmask can also be applied to embodiments where the multi-layer hardmask (or a layer therein) is replaced with a graded layer hardmask. For example, a graded layer hardmask may be used instead of a multi-layer hardmask in the context of the methods described in FIGS. 4, 6, 8, and 10.

### Apparatus

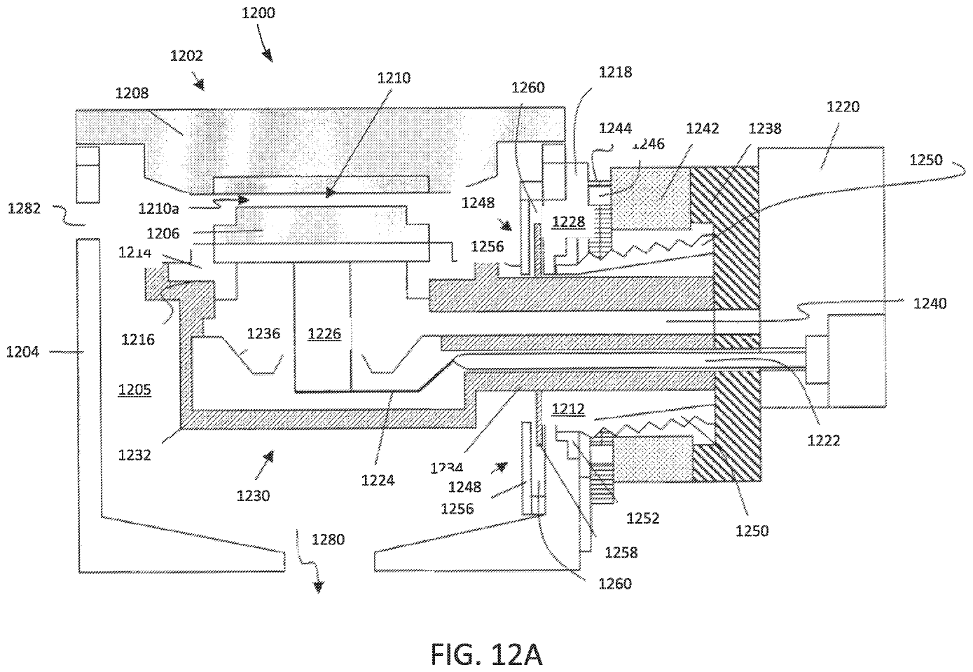

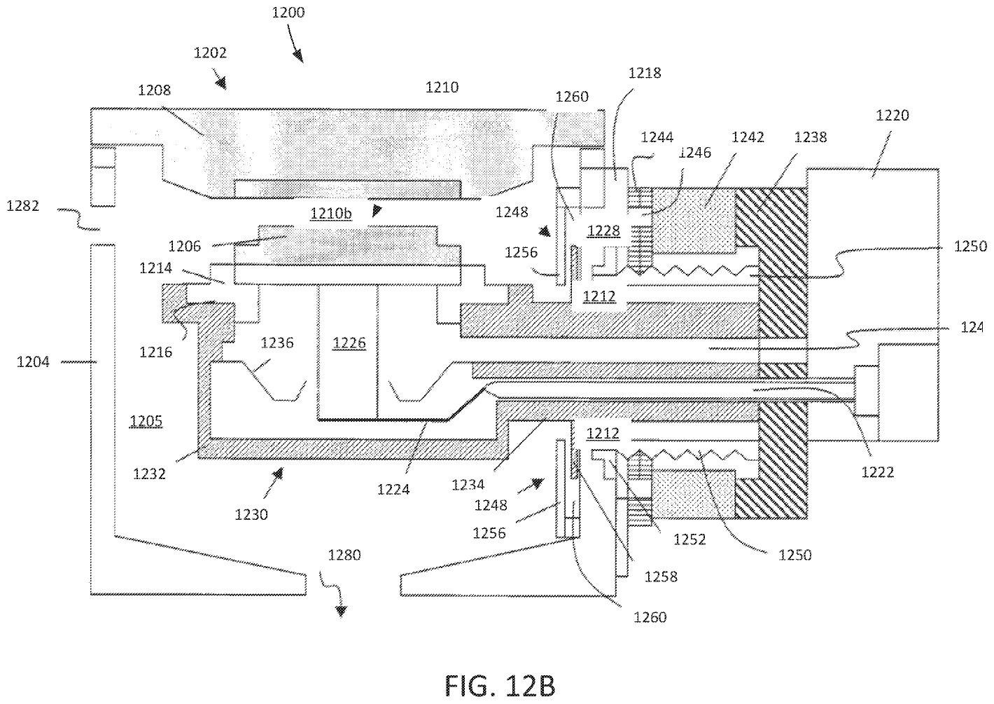

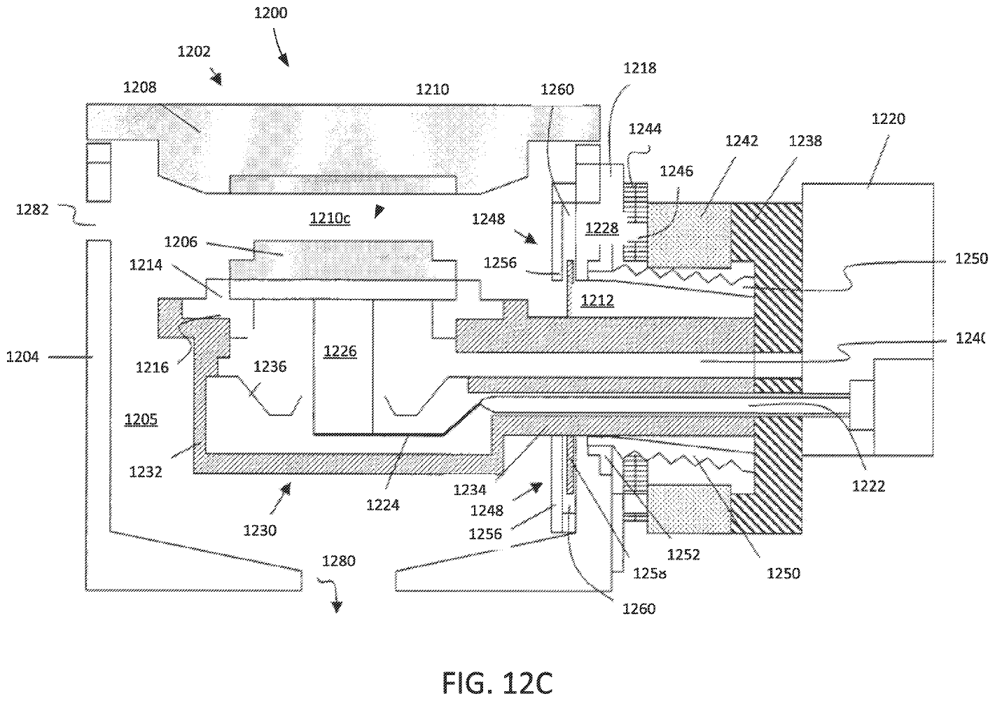

FIGS. 12A-12C illustrate an embodiment of an adjustable gap capacitively coupled confined RF plasma reactor 1200 that may be used for performing the etching operations described herein. As depicted, a vacuum chamber 1202 includes a chamber housing 1204, surrounding an interior space housing a lower electrode 1206. In an upper portion of the chamber 1202 an upper electrode 1208 is vertically spaced apart from the lower electrode 1206. Planar surfaces of the upper and lower electrodes 1208, 1206 are substantially parallel and orthogonal to the vertical direction between the electrodes. Preferably the upper and lower electrodes 1208, 1206 are circular and coaxial with respect to a vertical axis. A lower surface of the upper electrode 1208 faces an upper surface of the lower electrode 1206. The spaced apart facing electrode surfaces define an adjustable gap 1210 therebetween. During operation, the lower electrode 1206 is supplied RF power by an RF power supply (match) 1220. RF power is supplied to the lower electrode 1206 though an RF supply conduit 1222, an RF strap 1224 and an RF power member 1226. A grounding shield 1236 may surround the RF power member 1226 to provide a more uniform RF field to the lower electrode 1206. As described in commonly-owned U.S. Pat. No. 7,732,728, the entire contents of which are herein incorporated by reference, a wafer is inserted through wafer port 1282 and supported in the gap 1210 on the lower electrode 1206 for processing, a process gas is supplied to the gap 1210 (e.g., via one or more inlet) and excited into plasma state by the RF power. The upper electrode 1208 can be powered or grounded.

In the embodiment shown in FIGS. 12A-12C, the lower electrode 1206 is supported on a lower electrode support plate 1216. An insulator ring 1214 interposed between the lower electrode 1206 and the lower electrode Support plate 1216 insulates the lower electrode 1206 from the support plate 1216.

An RF bias housing 1230 supports the lower electrode 1206 on an RF bias housing bowl 1232. The bowl 1232 is connected through an opening in a chamber wall plate 1218 to a conduit support plate 1238 by an arm 1234 of the RF bias housing 1230. In a preferred embodiment, the RF bias housing bowl 1232 and RF bias housing arm 1234 are integrally formed as one component, however, the arm 1234 and bowl 1232 can also be two separate components bolted or joined together.

The RF bias housing arm 1234 includes one or more hollow passages for passing RF power and facilities, such as gas coolant, liquid coolant, RF energy, cables for lift pin control, electrical monitoring and actuating signals from outside the vacuum chamber 1202 to inside the vacuum chamber 1202 at a space on the backside of the lower electrode 1206. The RF supply conduit 1222 is insulated from the RF bias housing arm 1234, the RF bias housing arm 1234 providing a return path for RF power to the RF power supply 1220. A facilities conduit 1240 provides a passageway for facility components. Further details of the facility components are described in U.S. Pat. Nos. 5,948,704 and 7,732,728 and are not shown here for simplicity of description. The gap 1210 is preferably surrounded by a confinement ring assembly or shroud (not shown), details of which can be found in commonly owned published U.S. Pat. No. 7,740,736 herein incorporated by reference. The interior of the vacuum chamber 1202 is maintained at a low pressure by connection to a vacuum pump through vacuum portal 1280 (also referred to as an outlet).

The conduit support plate 1238 is attached to an actuation mechanism 1242. Details of an actuation mechanism are described in commonly-owned U.S. Pat. No. 7,732,728 incorporated herein by above. The actuation mechanism 1242, such as a servo mechanical motor, stepper motor or the like is attached to a vertical linear bearing 1244, for example, by a screw gear 1246 such as a ball screw and motor for rotating the ball screw. During operation to adjust the size of the gap 1210, the actuation mechanism 1242 travels along the vertical linear bearing 1244. FIG. 12A illustrates the arrangement when the actuation mechanism 1242 is at a high position on the linear bearing 1244 resulting in a small gap 1210 a. FIG. 12B illustrates the arrangement when the actuation mechanism 1242 is at a mid position on the linear bearing 1244. As shown, the lower electrode 1206, the RF bias housing 1230, the conduit support plate 1238, the RF power supply 1220 have all moved lower with respect to the chamber housing 1204 and the upper electrode 1208, resulting in a medium size gap 1210 b.

FIG. 12C illustrates a large gap 1210 c when the actuation mechanism 1242 is at a low position on the linear bearing. Preferably, the upper and lower electrodes 1208, 1206 remain coaxial during the gap adjustment and the facing surfaces of the upper and lower electrodes across the gap remain parallel.

This embodiment allows the gap 1210 between the lower and upper electrodes 1206, 1208 in the CCP chamber 1202 during multi-step process recipes (BARC, HARC, and STRIP etc.) to be adjusted, for example, in order to maintain uniform etch across a large diameter substrate such as 300 mm wafers or flat panel displays. In particular, this chamber pertains to a mechanical arrangement that permits the linear motion necessary to provide the adjustable gap between lower and upper electrodes 1206, 1208.

FIG. 12A illustrates laterally deflected bellows 1250 sealed at a proximate end to the conduit support plate 1238 and at a distal end to a stepped flange 1228 of chamber wall plate 1218. The inner diameter of the stepped flange defines an opening 1212 in the chamber wall plate 1218 through which the RF bias housing arm 1234 passes. The distal end of the bellows 1250 is clamped by a clamp ring 1252.

The laterally deflected bellows 1250 provides a vacuum seal while allowing vertical movement of the RF bias housing 1230, conduit support plate 1238 and actuation mechanism 1242. The RF bias housing 1230, conduit support plate 1238 and actuation mechanism 1242 can be referred to as a cantilever assembly. Preferably, the RF power supply 1220 moves with the cantilever assembly and can be attached to the conduit support plate 1238. FIG. 12B shows the bellows 1250 in a neutral position when the cantilever assembly is at a mid position. FIG. 12C shows the bellows 1250 laterally deflected when the cantilever assembly is at a low position.

A labyrinth seal 1248 provides a particle barrier between the bellows 1250 and the interior of the plasma processing chamber housing 1204. A fixed shield 1256 is immovably attached to the inside inner wall of the chamber housing 1204 at the chamber wall plate 1218 so as to provide a labyrinth groove 1260 (slot) in which a movable shield plate 1258 moves vertically to accommodate vertical movement of the cantilever assembly. The outer portion of the movable shield plate 1258 remains in the slot at all vertical positions of the lower electrode 1206.

In the embodiment shown, the labyrinth seal 1248 includes a fixed shield 1256 attached to an inner surface of the chamber wall plate 1218 at a periphery of the opening 1212 in the chamber wall plate 1218 defining a labyrinth groove 1260. The movable shield plate 1258 is attached and extends radially from the RF bias housing arm 1234 where the arm 1234 passes through the opening 1212 in the chamber wall plate 1218. The movable shield plate 1258 extends into the labyrinth groove 1260 while spaced apart from the fixed shield 1256 by a first gap and spaced apart from the interior surface of the chamber wall plate 1218 by a second gap allowing the cantilevered assembly to move vertically. The labyrinth seal 1248 blocks migration of particles spalled from the bellows 1250 from entering the vacuum chamber interior 1205 and blocks radicals from process gas plasma from migrating to the bellows 1250 where the radicals can form deposits which are subsequently spalled.

FIG. 12A shows the movable shield plate 1258 at a higher position in the labyrinth groove 1260 above the RF bias housing arm 1234 when the cantilevered assembly is in a high position (small gap 1210 a). FIG. 12C shows the movable shield plate 1258 at a lower position in the labyrinth groove 1260 above the RF bias housing arm 1234 when the cantilevered assembly is in a low position (large gap 1210 c). FIG. 12B shows the movable shield plate 1258 in a neutral or mid position within the labyrinth groove 1260 when the cantilevered assembly is in a mid position (medium gap 1210 b). While the labyrinth seal 1248 is shown as symmetrical about the RF bias housing arm 1234, in other embodiments the labyrinth seal 1248 may be asymmetrical about the RF bias arm 1234.

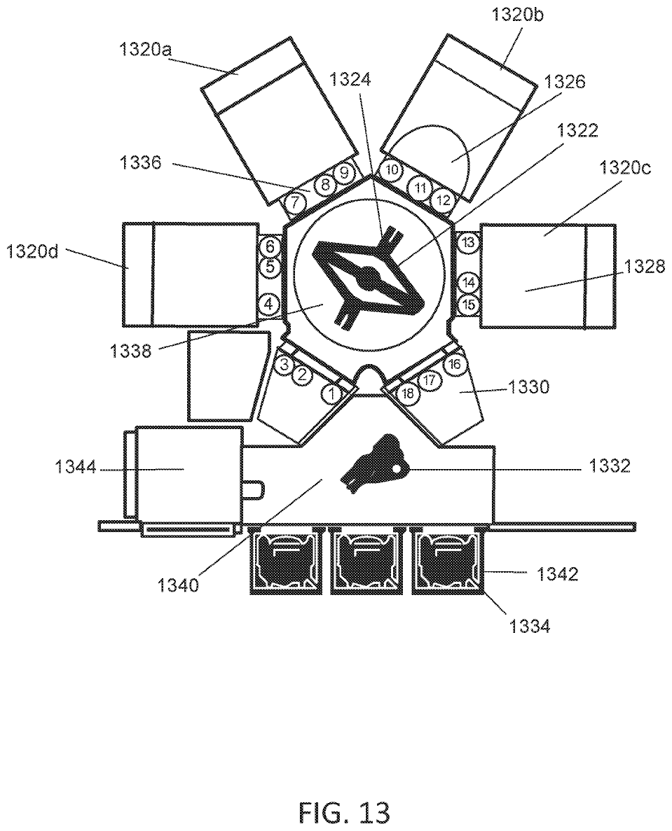

FIG. 13 depicts a semiconductor process cluster architecture with various modules that interface with a vacuum transfer module 1338 (VTM). The arrangement of transfer modules to “transfer” substrates among multiple storage facilities and processing modules may be referred to as a “cluster tool architecture” system. Airlock 1330, also known as a loadlock or transfer module, is shown in VTM 1338 with four processing modules 1320a-1320d, which may be individually optimized to perform various fabrication processes. By way of example, processing modules 1320a-1320d may be implemented to perform substrate etching, deposition, ion implantation, substrate cleaning, sputtering, and/or other semiconductor processes as well as laser metrology and other defect detection and defect identification methods. One or more of the processing modules (any of 1320a-1320d) may be implemented as disclosed herein, i.e., for etching recessed features into substrates using a multi-stage etch process with a multi-layer hardmask. Airlock 1330 and process modules 1320a-1320d may be referred to as “stations.” Each station has a facet 1336 that interfaces the station to VTM 1338. Inside the facets, sensors 1-18 are used to detect the passing of substrate 1326 when moved between respective stations.

Robot 1322 transfers substrates between stations. In one implementation, the robot may have one arm, and in another implementation, the robot may have two arms, where each arm has an end effector 1324 to pick substrates for transport. Front-end robot 1332, in atmospheric transfer module (ATM) 1340, may be used to transfer substrates from cassette or Front Opening Unified Pod (FOUP) 1334 in Load Port Module (LPM) 1342 to airlock 1330. Module center 1328 inside process modules 1320a-1320d may be one location for placing the substrate. Aligner 1344 in ATM 1340 may be used to align substrates.

In an exemplary processing method, a substrate is placed in one of the FOUPs 1334 in the LPM 1342. Front-end robot 1332 transfers the substrate from the FOUP 1334 to the aligner 1344, which allows the substrate 1326 to be properly centered before it is etched, or deposited upon, or otherwise processed. After being aligned, the substrate is moved by the front-end robot 1332 into an airlock 1330. Because airlock modules have the ability to match the environment between an ATM and a VTM, the substrate is able to move between the two pressure environments without being damaged. From the airlock module 1330, the substrate is moved by robot 1322 through VIM 1338 and into one of the process modules 1320a-1320d, for example process module 1320a. In order to achieve this substrate movement, the robot 1322 uses end effectors 1324 on each of its arms. In process module 1320a, the substrate undergoes etching as described. Next, the robot 1322 moves the substrate out of processing module 1320a to its next desired position.

It should be noted that the computer controlling the substrate movement can be local to the cluster architecture, or can be located external to the cluster architecture in the manufacturing floor, or in a remote location and connected to the cluster architecture via a network.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method of etching a feature into a substrate, the method comprising:
receiving a substrate in a process chamber, the substrate comprising:
dielectric material, and
a hardmask comprising an upper portion and a lower portion, the upper portion comprising carbon, and the lower portion comprising at least one material selected from the group consisting of: doped carbon, silicon, a metal, a metal-containing material, and combinations thereof,
wherein the upper portion and lower portion of the hardmask have different compositions,
wherein the hardmask is patterned to define a location where the feature will be etched in the dielectric material, and
wherein the hardmask is positioned over the dielectric material;
etching the feature to a first depth into the substrate while the substrate is at a first temperature and while the upper portion of the hardmask is exposed; and
etching the feature to a final depth while the substrate is at a second temperature and while the lower portion of the hardmask is exposed, wherein the second temperature is higher than the first temperature.

2. The method of claim 1, wherein the first temperature is between about −100° C. and about 0° C., and the second temperature is between about 0° C. and about 100° C.

3. The method of claim 2, wherein the first temperature is between about −60° C. and about −20° C., and the second temperature is between about 20° C. and about 60° C.

4. The method of claim 1, wherein the lower portion of the hardmask comprises one or more metal selected from the group consisting of aluminum, boron, chromium, cobalt, hafnium, molybdenum, niobium, ruthenium, tantalum, titanium, tungsten, vanadium, zirconium, and combinations thereof.

5. The method of claim 4, wherein the lower portion of the hardmask has a composition that is at least about 5 at % metal.

6. The method of claim 1, further comprising exposing the substrate to an oxygen-containing plasma to ash away any remaining upper portion of the hardmask after etching the feature to the first depth into the substrate and before etching the feature to the final depth.

7. The method of claim 1, further comprising depositing a liner on sidewalls of the feature after etching the feature to the first depth into the substrate and before etching the feature to the final depth.

8. The method of claim 1, further comprising depositing additional mask material on the hardmask after etching the feature to the first depth into the substrate and before etching the feature to the final depth.

9. The method of claim 1, wherein the upper portion and lower portion of the hardmask are distinct layers.

10. The method of claim 1, wherein the hardmask has a graded composition, such that a composition of the upper portion of the hardmask is graded into a composition of the lower portion of the hardmask.

11. An apparatus for etching a substrate, the apparatus comprising:
a process chamber;
a substrate support configured to support the substrate in the process chamber;
an inlet to the process chamber for introducing one or more reactants to the process chamber;
an outlet to the process chamber for removing materials from the process chamber;
a controller comprising a memory and a processor, wherein the controller is configured to cause:
receiving the substrate in the process chamber, the substrate comprising:
dielectric material, and
a hardmask comprising an upper portion and a lower portion, the upper portion comprising carbon, and the lower portion comprising at least one material selected from the group consisting of doped carbon, silicon, a metal, a metal-containing material, and combinations thereof,
wherein the upper portion and lower portion of the hardmask have different compositions,
wherein the hardmask is patterned to define a location where the feature will be etched in the dielectric material, and
wherein the hardmask is positioned over the dielectric material;
etching the feature to a first depth into the substrate while the substrate is at a first temperature and while the upper portion of the hardmask is exposed; and
etching the feature to a final depth while the substrate is at a second temperature and while the lower portion of the hardmask is exposed, wherein the second temperature is higher than the first temperature.

12. The apparatus of claim 11, wherein the first temperature is between about −100° C. and about 0° C., and the second temperature is between about 0° C. and about 100° C.

13. The apparatus of claim 12, wherein the first temperature is between about −60° C. and about −20° C., and the second temperature is between about 20° C. and about 60° C.

14. The apparatus of claim 11, wherein the lower portion of the hardmask comprises one or more metal selected from the group consisting of aluminum, boron, chromium, cobalt, hafnium, molybdenum, niobium, ruthenium, tantalum, titanium, tungsten, vanadium, zirconium, and combinations thereof.

15. The apparatus of claim 14, wherein the lower portion of the hardmask has a composition that is at least about 5 at % metal.

16. The apparatus of claim 11, wherein the controller is further configured to cause exposing the substrate to an oxygen-containing plasma to ash away any remaining upper portion of the hardmask after etching the feature to the first depth into the substrate and before etching the feature to the final depth.

17. The apparatus of claim 11, wherein the controller is further configured to cause depositing a liner on sidewalls of the feature after etching the feature to the first depth into the substrate and before etching the feature to the final depth.

18. The apparatus of claim 11, wherein the controller is further configured to cause depositing additional mask material on the hardmask after etching the feature to the first depth into the substrate and before etching the feature to the final depth.

19. The apparatus of claim 11, wherein the upper portion and lower portion of the hardmask are distinct layers.

20. The apparatus of claim 11, wherein the hardmask has a graded composition, such that a composition of the upper portion of the hardmask is graded into a composition of the lower portion of the hardmask.
